(19) United States
(12) Patent Application Publication
(10) Pub. No.: US 2019/0392774 A1
(43) Pub. Date: Dec. 26, 2019

(54) DISPLAY DEVICE AND DISPLAY PANEL THEREOF

(71) Applicants: HKC Corporation Limited, Shenzhen City (CN); Chongqing HKC Optoelectronics Technology Co., Itd., Chongqing (CN)

(72) Inventor: SHUOZHEN LIANG, Chongqing (CN)

(21) Appl. No.: 16/160,115

(22) Filed: Oct. 15, 2018

Related U.S. Application Data
(63) Continuation of application No. PCT/CN2018/092365, filed on Jun. 22, 2018.

(51) Int. Cl. G09G 3/36; H01L 27/12; G02F 1/1345; G02F 1/1362

(52) U.S. Cl. CPC G09G 3/3674; H01L 27/124; G09G 2300/0426; G02F 1/136286; G09G 3/3688; G02F 1/13452

(57) ABSTRACT

A display device and a display panel thereof are provided. The display panel includes a display region configured to display an image and a non-display region disposed to surround the display region. The display region is disposed with a transistor array substrate. The non-display region is disposed with a source control chip and a gate control chip. The source control chip is electrically connected to a source electrode of a transistor in the thin film transistor array substrate by data lines. The gate control chip is electrically connected to a gate electrode of the transistor by scan lines. The source control chip and the gate control chip are located on an identical side of the display region.

### FIELD OF THE DISCLOSURE

The disclosure relates to a display technical field, and more particularly to a display device and a display panel thereof.

### BACKGROUND

In order to control the signal switch of a display, liquid crystal displays generally are equipped with gate control chips and source control chips to govern switches of thin film transistors. In a conventional display, the gate control chip is connected with the gate electrode of the thin film transistor by the gate scan line; the source control chip is connected with the source electrode of the thin film transistor by the source data line. As the gate control chip and the gate scan line are disposed transversely, and the source control chip and the source data line are disposed lengthwise, the gate scan line generally is called as a transverse scan line, and the source data line is called as a lengthwise data line. Therefore, transverse and lengthwise directions of the display both need to be disposed with placing regions, resulting in unsatisfying the development requirement of narrow borders.

### SUMMARY

Accordingly, a display panel with narrow borders is necessary to be provided. A display device is further provided.

The disclosure provides a display panel, including: a display region configured to display images, and a non-display region. The display region includes a thin film transistor array substrate. The non-display region is disposed to surround the display region. The non-display region includes: a source control chip and a gate control chip. The source control chip is electrically connected to a source electrode of a transistor in the thin film transistor array substrate by data lines; the source control chip is fixated on a flexible circuit board by a manner of chip on film. The gate control chip is electrically connected to a gate electrode of the transistor by scan lines; the gate control chip is fixated on the flexible circuit board by the manner of chip on film; the source control chip and the gate control chip are located on an identical side of the display region. The number of the transistors transverse in each row of the thin film transistor array substrate is larger than the number of the transistors lengthwise in each column of the thin film transistor array substrate; the source control chip and the gate control chip are located on transverse sides of the display region. A thin film transistor in the thin film transistor array substrate is a dual-gate transistor; the gate control chip includes a first gate control chip and a second gate control chip; the first gate control chip, the source control chip and the second gate control chip are disposed abreast in sequence along an identical side of the display region.

The disclosure provides a display panel, including: a display region configured to display images, and a non-display region. The display region includes a thin film transistor array substrate. The non-display region is disposed to surround the display region. The non-display region includes: a source control chip and a gate control chip. The source control chip is electrically connected to a source electrode of a transistor in the thin film transistor array substrate by data lines. The source control chip is electrically connected to a source electrode of a transistor in the thin film transistor array substrate by data lines.

In one of the embodiments, a thin film transistor in the thin film transistor array substrate is a mono-gate transistor. The gate control chip and the source control chip are disposed abreast in sequence along an identical side of the display region.

In one of the embodiments, a thin film transistor in the thin film transistor array substrate is a dual-gate transistor; the gate control chip includes a first gate control chip and a second gate control chip; the first gate control chip, the source control chip and the second gate control chip are disposed abreast in sequence along an identical side of the display region.

In one of the embodiments, the number of transistors transverse in each row of the thin film transistor array substrate and the number of transistors lengthwise in each column of the thin film transistor array substrate are different; the source control chip and the gate control chip are disposed abreast in sequence along a direction with more transistors.

In one of the embodiments, the number of the transistors transverse in each row of the thin film transistor array substrate is larger than the number of the transistors lengthwise in each column of the thin film transistor array substrate; the source control chip and the gate control chip are located on transverse sides of the display region.

In one of the embodiments, a thin film transistor in the thin film transistor array substrate is a mono-gate transistor; the gate control chip and the source control chip are disposed abreast in sequence on transverse sides of the display region.

In one of the embodiments, a thin film transistor in the thin film transistor array substrate is a dual-gate transistor; the gate control chip includes a first gate control chip and a second gate control chip; the first gate control chip, the source control chip and the second gate control chip are disposed abreast in sequence on transverse sides of the display region.

In one of the embodiments, the source control chip and the gate control chip both are fixated on a flexible circuit board by a manner of chip on film.

In one of the embodiments, the source control chip and the gate control chip both are fixated on a flexible circuit board by a manner of tape carrier package.

A display device includes: a display control component, and a display panel; the display panel is the display panel in any one of the embodiments above; the display control component and the display panel are electrically connected to control the display panel.

In the display panel above, the source control chip and the gate control chip are disposed on the same side of the display region, and the non-display region of the other three sides of the display region does not request to spare positions for chips, resulting in achieving a display panel with narrow borders. Meanwhile, as the source control chip and the gate control chip are disposed on the same side of the display region; the source control chip and the gate control chip can be bonded in the same bonding process, resulting in one less bonding process compared with the conventional display panel. The manufacturing cost can be reduced and the production efficiency is improved.

### BRIEF DESCRIPTION OF THE DRAWINGS

FIG. 1 is a structural block diagram of an exemplary liquid crystal display;

FIG. 2 is a structural block diagram of a liquid crystal display with a mono-gate thin film transistor array substrate in an embodiment of the disclosure;

FIG. 3 is a structural schematic view of the liquid crystal display in FIG. 2;

FIG. 4 is a structural block diagram of a liquid crystal display with a dual-gate thin film transistor array substrate in an embodiment of the disclosure;

FIG. 5 is a structural schematic view of the liquid crystal display in FIG. 4;

FIG. 6 is a structural block diagram of a liquid crystal display device with a mono-gate thin film transistor array substrate in an embodiment of the disclosure.

### DETAILED DESCRIPTION OF PREFERRED EMBODIMENTS

In order to better clarify the objective, solutions and advantages of the disclosure, the disclosure will be further illustrated in detail with reference to embodiments and accompanying drawings as follows. Comprehensively, concrete embodiments described herein are purely for explaining the disclosure, rather than limiting the disclosure.

In some examples, the source control chip and the gate control chip of a display panel respectively are disposed on two adjacent sides of the display region, and the border of the display panel is relatively large, failing in satisfying the requirement of narrow borders of the display panel. The embodiment provides a display panel with narrow borders. The display panel includes a display region and a non-display region. The display region is configured to display images. The display region is disposed with a transistor array substrate. The non-display region is disposed to surround the display region. The non-display region is disposed with a source control chip and a gate control chip. The source control chip is electrically connected with the source electrode of the transistor in the transistor array substrate by data lines. The gate control chip is electrically connected with the gate electrode of the transistor by scan lines. The source control chip and the gate control chip are disposed on the same side of the display region.

In the display panel above, the source control chip and the gate control chip are disposed on the same side of the display region, and the non-display region of the other three sides of the display region does not request to spare positions for chips, resulting in achieving a display panel with narrow borders. Meanwhile, as the source control chip and the gate control chip are disposed on the same side of the display region; the source control chip and the gate control chip can be bonded in the same bonding process, resulting in one less bonding process compared with the conventional display panel. The manufacturing cost can be reduced and the production efficiency is improved.

The embodiment will be further illustrated combined with the liquid crystal display panel among display panels.

The liquid crystal display includes a display region and a non-display region. The display region includes a lower polarizer, a thin film transistor (TFT) array substrate, a liquid crystal layer, a color filter (CF) substrate and an upper polarizer. The thin film transistor in the thin film transistor array substrate can be a mono-gate thin film transistor or a dual-gate thin film transistor.

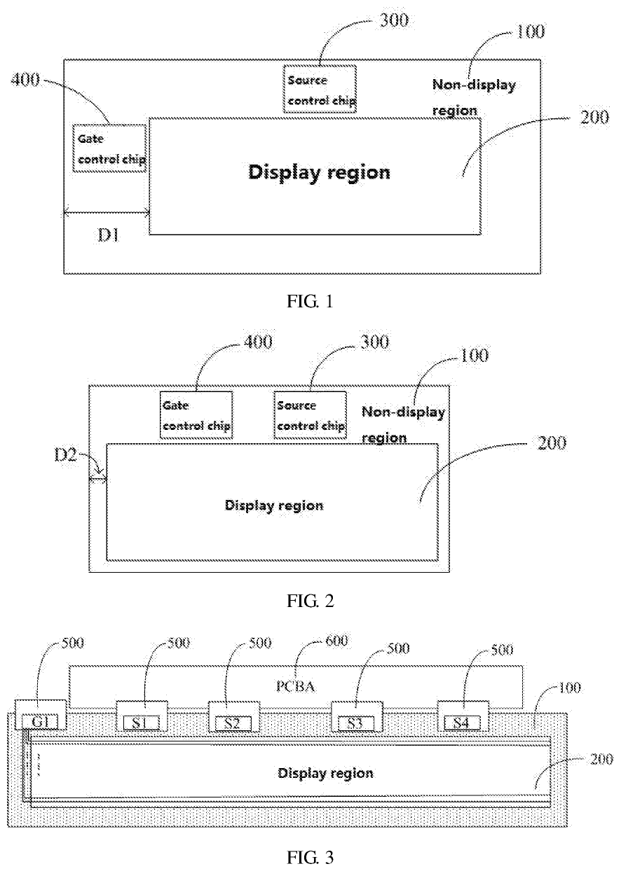

The non-display region is disposed to surround the display region. In an embodiment, the non-display region can include a display-shielding region and a border region of a liquid crystal display. In another embodiment, the non-display region can merely be the display-shielding region of the liquid crystal display to meet the requirement in developing liquid crystal displays with narrow borders. The non-display region is disposed with a source control chip and a gate control chip. The source control chip is electrically connected with the source electrode of the thin film transistor in the thin film transistor array substrate by data lines; the gate control chip is electrically connected with the gate electrode of the thin film transistor in the thin film transistor array substrate by scan lines; the source control chip and the gate control chip control the thin film transistor array for displaying images on the display region. In the conventional liquid crystal display, the source control chip and the gate control chip respectively are disposed on adjacent sides of the display region, and borders of the liquid crystal display is relatively large, failing in satisfying the requirement for narrow borders of liquid crystal displays, as shown in FIG. 1. A gate control chip 400 and a source control chip 300 respectively are disposed on two adjacent sides of a display region 200, and the width of the non-display region 100 with the gate control chip 400 and the source control chip 300 is relatively large. In the disclosure, the width of the non-display region 100 indicates the distance from the outermost edge of the non-display region 100 to the edge of the display region 200. The non-display region 100 on the left side and the upper side of the display region 200 are respectively disposed with the gate control chip 400 and the source control chip 300 in FIG. 1, and the width D1 of the non-display region on the left side of the display region 200 cannot be narrow, failing in meeting the requirement for narrow borders of liquid crystal displays.

The embodiment of the disclosure provides a liquid crystal display to satisfy the requirement for developing narrow borders. In the liquid crystal display in the embodiment, the source control chip and the gate control chip in the non-display region are disposed on the same side of the display region, the non-display region on the other three sides of the display region does not need to spare positions for chips. Therefore, the width of the other three sides can be reduced to achieve narrow borders of the liquid crystal displays. Meanwhile, as the source control chip and the gate control chip are disposed on the same side of the display region, the source control chip and the gate control chip can be bonded in the same bonding process, resulting in one less bonding process. The manufacturing cost can be reduced and the production efficiency is improved.

In an embodiment, the number of thin film transistors transverse in each row of the thin film transistor array substrate and the number of thin film transistors lengthwise in each column are different. The gate control chip and the source control chip are disposed abreast in sequence along a direction with more thin film transistors. For instance, in a bar display (the number of thin film transistors in the lengthwise direction of the thin film transistor array is relatively small), the gate control chip and the source control chip both are disposed on transverse sides of the display region, namely the gate control chip and the source control chip are disposed in non-display region along the lengthwise direction of the display region. In other embodiments, when the number of thin film transistors transverse in the thin film transistor array is relatively small, the gate control chip and the source control chip both are disposed on lengthwise sides of the display region, namely the gate control chip and the source control chip are sequentially disposed in the non-display region along the widthwise direction of the display region. In the embodiment, the gate control chip and the source control chip both are fixated on the flexible circuit board by a manner of chip on film (COF). In other embodiments, the gate control chip and the source control chip both are fixated on the flexible circuit board by a manner of tape carrier package (TCP).

The liquid crystal display in the embodiment will be further illustrated in detail with two conditions, respectively are the thin film transistor in the thin film transistor array is a mono-gate thin film transistor and the dual-gate thin film transistor as follows.

FIG. 2 is a structural block diagram of a liquid crystal display adopting the thin film transistor array substrate with a single-gate in an embodiment. As shown in FIG. 2, the gate control chip 400 and the source control chip 300 are disposed in the non-display region 100 on the same side of the display region 200; the gate control chip 400 and the source control chip 300 are disposed abreast in sequence along the same side of the display region 200. In the embodiment, the liquid crystal display is a bar display; the gate control chip 400 and the source control chip 300 sequentially are disposed in the non-display region 100 along transverse sides of the display region 200/sequentially disposed in the non-display region 100 along the lengthwise direction of the display region). The non-display region 100 on the other sides of the display region 200 is unnecessary to spare positions for chips. The non-display region on the other three sides of the display region 200 in FIG. 2 is unnecessary to be disposed with control chips to allow a width D2 of the corresponding non-display region 100 can be reduced to a target size according to requirements for fulfilling the requirement of developing narrow borders. Meanwhile, the gate control chip 400 and the source control chip 300 are disposed in the non-display region 100 on the same side of the display region 200. The source control chip 300 and the gate control chip 400 can be bonded in the same bonding process, resulting in one less bonding process. The manufacturing cost can be reduced and the production efficiency is improved.

FIG. 3 is a structural schematic view of a liquid crystal display in FIG. 2. As shown in FIG. 3, the gate control chip 400 is a gate control chip G1. The source control chip 300 includes a source control chip S1, a source control chip S2, a source control chip S3 and a source control chip S4. The gate control chip G1 is connected with the gate electrode of the thin film transistor in the display region 200 by scan lines. The source control chip S1, the source control chip S2, the source control chip S3 and the source control chip S4 respectively are fixated on the flexible circuit board 500 by COF, and connected with a printed circuit board assembly (PCBA) 600 by a flexible circuit board 500. The source control chip S1, the source control chip S2, the source control chip S3 and the source control chip S4 are further connected with the source electrode of the thin film transistor in the display region 200 by data lines. The source control chip S1, the source control chip S2, the source control chip S3, the source control chip S4 and the gate control chip G1 control thin film transistor array to fulfill the image display in the display region.

The gate control chip G1 and the source control chip S1 are disposed on the same side of the display region 200, as a result, the non-display region 100 on the other three sides of the display region 200 is unnecessary to pre-spare positions for the gate control chip G1 to fulfill the narrow borders of the non-display region 100 on the other three sides. The gate control chip G1, the source control chip S1, the source control chip S2, the source control chip S3 and the source control chip S4 are disposed on the same side of the display region 200. The gate control chip G1, the source control chip S1, the source control chip S2, the source control chip S3 and the source control chip S4 can be bonded in the same bonding process, resulting in one less bonding process. The manufacturing cost can be reduced and the production efficiency is improved. The number of source control chips and the gate control chips in the embodiment merely is exemplary. In other embodiments, the number can further be determined according to the size of the liquid crystal display and the structure of the control chip.

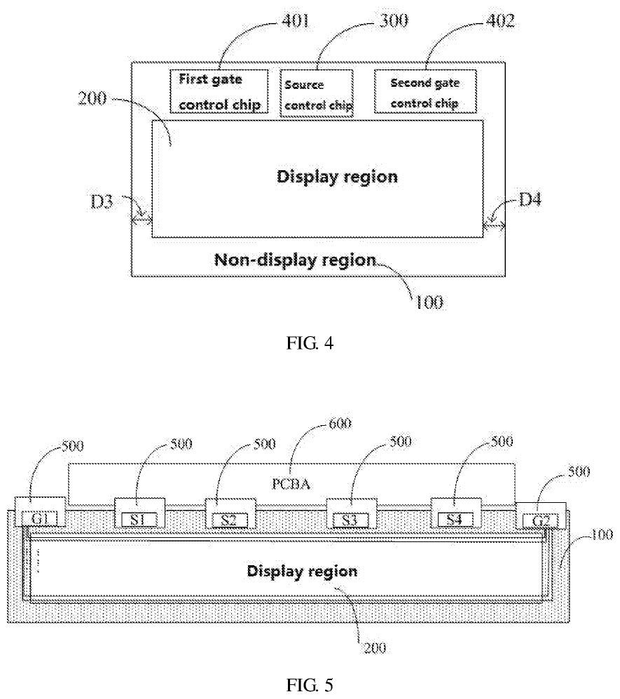

FIG. 4 is a structural block diagram of a liquid crystal display with a dual-gate thin film transistor array substrate. In the embodiment, the gate control chip includes a first gate control chip 401 and a second gate control chip 402. The first gate control chip 401 and the second gate control chip 402 respectively control two gate electrodes of the thin film transistor. The first gate control chip 401, the source control chip 300 and the second gate control chip 402 are disposed on the same side of the display region 200, and sequentially disposed in the non-display region 100 along the same side of the display region 200. The number of thin film transistors transverse in each row of the thin film transistor array substrate and the number of thin film transistors lengthwise in each column are different. The first gate control chip 401, the source control chip 300 and the second gate control chip 402 are disposed abreast in sequence along a direction with more thin film transistors. In the embodiment, the liquid crystal display is a bar display. The first gate control chip 401, the source control chip 300 and the second gate control chip 402 are disposed on transverse sides of the display region 200. The non-display region 100 of the other three sides of the display region 200 does not request to spare positions for chips, resulting in further reducing the width of the corresponding region of the non-display region 100, and the width D3 and the width D4 can be reduced to the target width according to the requirement so as to fulfill the requirement for narrow borders of the liquid crystal display. Meanwhile, as the first gate control chip 401, the second gate control chip 402 and the source control chip 300 are disposed on the same side, the source control chip and the gate control chip can be bonded in the same bonding process, further resulting in one less bonding process. The manufacturing cost can be reduced and the production efficiency is improved.

FIG. 5 is a structural schematic view of a liquid crystal display in FIG. 4. As shown in FIG. 5, the first gate control chip 401 is the gate control chip G1, and the second gate control chip 402 is the gate control chip G2. The source control chip 300 includes a source control chip S1, a source control chip S2, a source control chip S3 and a source control chip S4. The gate control chip G1 and the gate control chip G2 respectively are connected with two gate electrodes of the thin film transistor in the display region 200 by scan lines to control the two gate electrodes of the thin film transistor. The dual-gate thin film transistor can enhance the ability in control to adapt the liquid crystal display with large sizes. The source control chip S1, the source control chip S2, the source control chip S3 and the source control chip S4 respectively are fixated on the flexible circuit board 500 by COF, and connected with a printed circuit board assembly (PCBA) 600 by a flexible circuit board 500. The source control chip S1, the source control chip S2, the source control chip S3 and the source control chip S4 are further connected with the source electrode of the thin film transistor by data lines. The source control chip S1, the source control chip S2, the source control chip S3, the source control chip S4, the gate control chip G1 and the gate control chip G2 control thin film transistor array to fulfill the image display in the display region.

The gate control chip G1, the gate control chip G2 and the source control chip S1 are disposed on the same side of the display region 200 to narrow the borders the non-display region 100 on the other three sides. The gate control chip G1, the gate control chip G2, the control chip S1, the source control chip S2, the source control chip S3 and the source control chip S4 are disposed on the same side of the display region. The gate control chip G1, the gate control chip G2, the control chip S1, the source control chip S2, the source control chip S3 and the source control chip S4 can be bonded in the same bonding process, resulting in one less bonding process. The manufacturing cost can be reduced and the production efficiency is improved. The number of source control chips and the gate control chip in the embodiment merely is exemplary. In other embodiments, the number can further be determined according to the size of the liquid crystal display and the structure of the control chip.

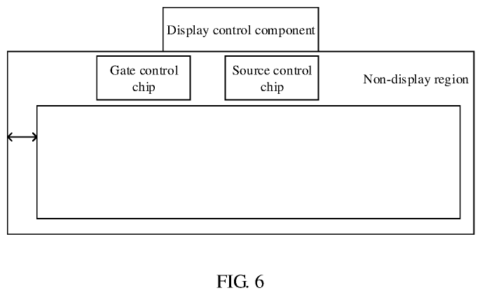

The disclosure further provides a liquid crystal display device, as shown in FIG. 6, FIG. 6 is a structural block diagram of a liquid crystal display device adopting the thin film transistor array substrate with a single-gate in the embodiment of the disclosure. The liquid crystal display device includes a display control component and a liquid crystal display. The liquid crystal display is the liquid crystal display in the embodiment as shown in FIG. 2. The display control component and the liquid crystal display are electrically connected to control the liquid crystal display. Comprehensively, the liquid crystal display can further be the liquid crystal display in any one of the embodiments above.

Each of the technical features of the embodiments above can be combined freely. For the sake of simplifying the description, not all of the possible combinations of each of the technical features in the aforementioned embodiments are described. However, as long as the combinations of the technical features are compatible, the combinations should be regarded as the scope recorded in the specification.

The description above merely depicts several embodiments of the disclosure; the description is relatively detailed and specific, but should not representing the limitation of the scope of the disclosure. A person skilled in the art can achieve the modification and improvement within the core of the disclosure, and the modification and improvement should be included in the protective scope of the disclosure. Therefore, the protective scope of the disclosure should be based on the attached claims.

What is claimed is:

1. A display panel comprising:
a display region, configured to display images; wherein the display region comprises a thin film transistor array substrate; and
a non-display region, wherein the non-display region is disposed to surround the display region; the non-display region comprises:
a source control chip, wherein the source control chip is electrically connected to a source electrode of a transistor in the thin film transistor array substrate by data lines, wherein the source control chip is fixated on a flexible circuit board by a manner of chip on film; and
a gate control chip, wherein the gate control chip is electrically connected to a gate electrode of the transistor by scan lines, wherein the gate control chip is fixated on the flexible circuit board by the manner of chip on film; the source control chip and the gate control chip are located on an identical side of the display region;
wherein a number of the transistors transverse in each row of the thin film transistor array substrate is larger than the number of the transistors lengthwise in each column of the thin film transistor array substrate; the source control chip and the gate control chip are located on transverse sides of the display region;
wherein a thin film transistor in the thin film transistor array substrate is a dual-gate transistor; the gate control chip comprises a first gate control chip and a second gate control chip; the first gate control chip, the source control chip and the second gate control chip are disposed abreast in sequence along an identical side of the display region.

2. A display panel comprising:
a display region, configured to display images; wherein the display region comprises a thin film transistor array substrate; and
a non-display region, wherein the non-display region is disposed to surround the display region; the non-display region comprises:
a source control chip, wherein the source control chip is electrically connected to a source electrode of a transistor in the thin film transistor array substrate by data lines; and
a gate control chip, wherein the gate control chip is electrically connected to a gate electrode of the transistor by scan lines; the source control chip and the gate control chip are located on an identical side of the display region.

3. The display panel according to claim 2, wherein a thin film transistor in the thin film transistor array substrate is a mono-gate transistor, the gate control chip and the source control chip are disposed abreast in sequence along an identical side of the display region.

4. The display panel according to claim 2, wherein a thin film transistor in the thin film transistor array substrate is a dual-gate transistor; the gate control chip comprises a first gate control chip and a second gate control chip; the first gate control chip, the source control chip and the second gate control chip are disposed abreast in sequence along an identical side of the display region.

5. The display panel according to claim 2, wherein the number of transistors transverse in each row of the thin film transistor array substrate and the number of transistors lengthwise in each column of the thin film transistor array substrate are different; the source control chip and the gate control chip are disposed abreast in sequence along a direction with more transistors.

6. The display panel according to claim 5, wherein the number of the transistors transverse in each row of the thin film transistor array substrate is larger than the number of the transistors lengthwise in each column of the thin film transistor array substrate; the source control chip and the gate control chip are located on transverse sides of the display region.

7. The display panel according to claim 6, wherein a thin film transistor in the thin film transistor array substrate is a mono-gate transistor, the gate control chip and the source control chip are disposed abreast in sequence on transverse sides of the display region.

8. The display panel according to claim 6, wherein a thin film transistor in the thin film transistor array substrate is a dual-gate transistor; the gate control chip comprises a first gate control chip and a second gate control chip; the first gate control chip, the source control chip and the second gate control chip are disposed abreast in sequence on transverse sides of the display region.

9. The display panel according to claim 2, wherein the source control chip and the gate control chip both are fixated on a flexible circuit board by a manner of chip on film.

10. The display panel according to claim 2, wherein the source control chip and the gate control chip both are fixated on a flexible circuit board by a manner of tape carrier package.

11. A display device comprising:
a display control component; and
a display panel; wherein the display control component and the display panel are electrically connected to control the display panel; the display panel comprises:
a display region, configured to display images; wherein the display region is disposed with a thin film transistor array substrate; and
a non-display region; wherein the non-display region is disposed to surround the display region; the non-display region comprises
a source control chip, wherein the source control chip is electrically connected to a source electrode of a transistor in the thin film transistor array substrate by data lines, the source control chip is fixated on a flexible circuit board by a manner of chip on film; and
a gate control chip, wherein the gate control chip is electrically connected to a gate electrode of the transistor by scan lines, the gate control chip is fixated on the flexible circuit board by the manner of chip on film; the source control chip and the gate control chip are located on an identical side of the display region.

12. The display device according to claim 11, wherein a thin film transistor in the thin film transistor array substrate is a mono-gate transistor, the gate control chip and the source control chip are disposed abreast in sequence along an identical side of the display region.

13. The display device according to claim 11, wherein a thin film transistor in the thin film transistor array substrate is a dual-gate transistor; the gate control chip comprises a first gate control chip and a second gate control chip; the first gate control chip, the source control chip and the second gate control chip are disposed abreast in sequence along an identical side of the display region.

14. The display device according to claim 11, wherein the number of transistors transverse in each row of the thin film transistor array substrate and the number of transistors lengthwise in each column of the thin film transistor array substrate are different; the source control chip and the gate control chip are disposed abreast in sequence along a direction with more transistors.

15. The display device according to claim 14, wherein the number of the transistors transverse in each row of the thin film transistor array substrate is larger than the number of the transistors lengthwise in each column of the thin film transistor array substrate; the source control chip and the gate control chip are located on transverse sides of the display region.

16. The display device according to claim 15, wherein a thin film transistor in the thin film transistor array substrate is a mono-gate transistor, the gate control chip and the source control chip are disposed abreast in sequence on transverse sides of the display region.

17. The display device according to claim 15, wherein a thin film transistor in the thin film transistor array substrate is a dual-gate transistor; the gate control chip comprises a first gate control chip and a second gate control chip; the first gate control chip, the source control chip and the second gate control chip are disposed abreast in sequence on transverse sides of the display region.

18. The display device according to claim 11, wherein the source control chip and the gate control chip both are fixated on a flexible circuit board by a manner of chip on film.

19. The display device according to claim 11, wherein the source control chip and the gate control chip both are fixated on a flexible circuit board by a manner of tape carrier package.

20. The display device according to claim 11, wherein the display control component comprises a flexible circuit board and a printed circuit board assembly.
